(19) United States
(12) Patent Application Publication
(10) Pub. No.: US 2005/0063491 A1
(43) Pub. Date: Mar. 24, 2005

(54) Radio frequency signal discrimination method and system

(75) Inventor: Brian Saloka, Roseville, MI (US)

Correspondence Address: SIEMENS CORPORATION;INTELLECTUAL PROPERTY LAW DEPARTMENT, 170 WOOD AVENUE SOUTH, ISELIN, NJ, 08830, US

(73) Assignee: Siemens VDO Automotive Corporation, Auburn Hills, MI (US)

(21) Appl. No.: 10/873,925

(22) Filed: Jun. 22, 2004

Related U.S. Application Data
(60) Provisional application No. 60/503,904, filed on Sep. 19, 2003.

(51) Int. Cl. H03D 3/00

(52) U.S. Cl. 375/322

(57) ABSTRACT

A signal detection and discrimination system discriminates between FSK modulated signals and ASK modulated signals and switches a signal receiver mode to accommodate the signal type. A first discrimination stage counts the number of pulses in the signal over a selected time window. If the number of pulses within the time window fall within a valid range, it indicates that the signal is ASK modulated and that there is possible incoming data on the signal. If the number of pulses falls outside the valid range, the pulses are considered noise or data at a different baud rate. If the data signal exhibits no pulses within the time window, it indicates that the data signal is FSK modulated and the receiver is switched from an ASK mode to an FSK mode.

### REFERENCE TO RELATED APPLICATIONS

The present invention claims the benefit of U.S. Provisional Patent Application No. 60/503,904, filed Sep. 19, 2003.

### TECHNICAL FIELD

The present invention is related to signal discrimination, and more particularly to discriminating among different types of radio frequency (RF) signals.

### BACKGROUND OF THE INVENTION

RF signals are used in many communication applications. A given application may require a receiver system that can receive both frequency-shift-keyed (FSK) modulated RF signals and amplitude-shift-keyed (ASK) modulated RF signals, but the specific modulation of a signal received at any given time can randomly change without warning. To accommodate both signal types, current applications incorporate two separate receivers, one to receive FSK signals and another to receive ASK signals. This undesirably increases the complexity of the application.

There is currently no way to detect and distinguish the difference between FSK and ASK modulated signals and to respond to the change in the modulation of a received signal.

### SUMMARY OF THE INVENTION

The present invention is directed to a signal detection and discrimination system that can discriminate between FSK signals and ASK signals and that can switch a signal receiver mode to accommodate the signal modulation type. In one embodiment, an ASK mode is the default mode. A given data input signal is evaluated in a first discrimination stage by counting edges, or pulses, in the signal over a selected time window. If the number of pulses within the time window fall within a valid range, it indicates that the signal is ASK modulated and that there is possible incoming data on the signal. If the number of pulses falls outside the valid range, the pulses are considered noise or data at a different baud rate.

If the data signal exhibits no pulses within the time window, it indicates that the data signal is FSK modulated and the receiver is switched to an FSK mode. The next FSK transmission is then received as incoming data. If the system does not see FSK data for a predetermined time period, the receiver is switched back to the ASK mode.

In one embodiment, the current consumption of the receiver can be reduced by running duty-cycle power to the receiver.

### BRIEF DESCRIPTION OF THE DRAWINGS

FIG. 1 is a representative block diagram of the inventive system according to one embodiment of the invention;

FIG. 2 is a flow diagram illustrating a method according to one embodiment of the invention;

FIG. 3 is a signal timing diagram illustrating a first signal discrimination stage according to one embodiment of the invention;

FIG. 4 is a signal timing diagram illustrating a signal receipt stage;

FIG. 5 is a signal timing diagram illustrating a second signal discrimination stage according to one embodiment of the invention.

### DETAILED DESCRIPTION OF THE EMBODIMENTS

The invention generally performs two levels of discrimination. First, it conducts a counter discrimination step that count the number of pulses in an incoming transmission within a given window to distinguish between ASK and FSK modulated transmissions and to detect whether a given incoming transmission is noise or data at a baud rate that is different than the desired baud rate. Second, the invention conducts a pulse width discrimination step that measures the pulse widths of the first several half-bits of the incoming transmission. If the pulse widths of the measured half-bits are determined to be within a valid time interval for one or more desired baud rates, then the invention considers the incoming transmission to contain valid data.

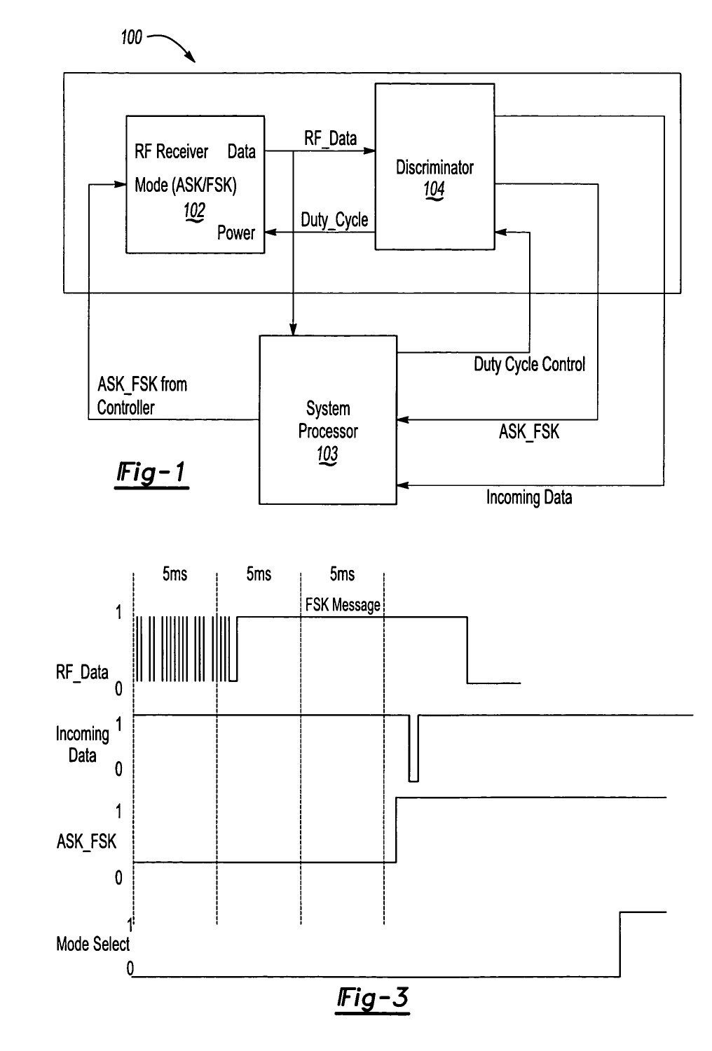

FIG. 1 is a representative block diagram illustrating a signal receiving system 100 according to one embodiment of the invention.

The system 100 includes a signal receiver 102 that receives a radio frequency (RF) signal transmission. The receiver 102 communicates with a system processor 103, such as a main microcontroller. The signal can be an amplitude-shift-keyed (ASK) modulated signal or a frequency-shift-keyed (FSK) modulated signal. It is assumed that the modulation of the signal can change randomly at any time. The signal itself may be, for example, a Manchester-encoded or variable pulse width signal, where each data bit is represented by at least one bit transition (i.e., from 0 to 1 or from 1 to 0).

The receiver 102 sends RF data to a discriminator 104. The discriminator 104 acts as an event informer to the system processor 103, sending an incoming data signal pulse to the system processor 103 to indicate that a valid signal transmission has been detected. In the illustrated embodiment, the data signal is sent to the system processor 103 as long as the discriminator 104 detects a valid signal. In other words, the discriminator 104 acts an interface between the receiver 102 and the system processor 103 to inform the system processor 103 that data may be coming to the system processor 103. The actual configuration of any system processor 103 outside of the receiving system 100 can vary without departing from the scope of the invention.

The discriminator 104 also sends an ASK_FSK indicator to the system processor 103 to indicate the modulation of the incoming transmission to that device. In the example shown in FIGS. 3 and 5, the ASK_FSK signal is low when the received data signal is ASK modulated and high when the received transmission is FSK modulated. The system processor 103 does the actual switching of the receiver 102 so that the receiver 102 is able to receive the ASK signal or FSK signal, depending on which type is being transmitted. Note that the discriminator 104 tells the system processor 103 whether a given received signal transmission is ASK or FSK modulated, while the system processor 103 instructs the receiver 102 to conduct the actual switching to the ASK mode or FSK mode.

As also shown in FIG. 1, the discriminator 104 may receive a duty cycle control input from the system processor 103 and control the power sent to the receiver 102 to either provide power to the receiver 102 continuously or, alternatively, to duty-cycle the power to the receiver 102 to minimize current consumption when the receiver 102 is inactive.

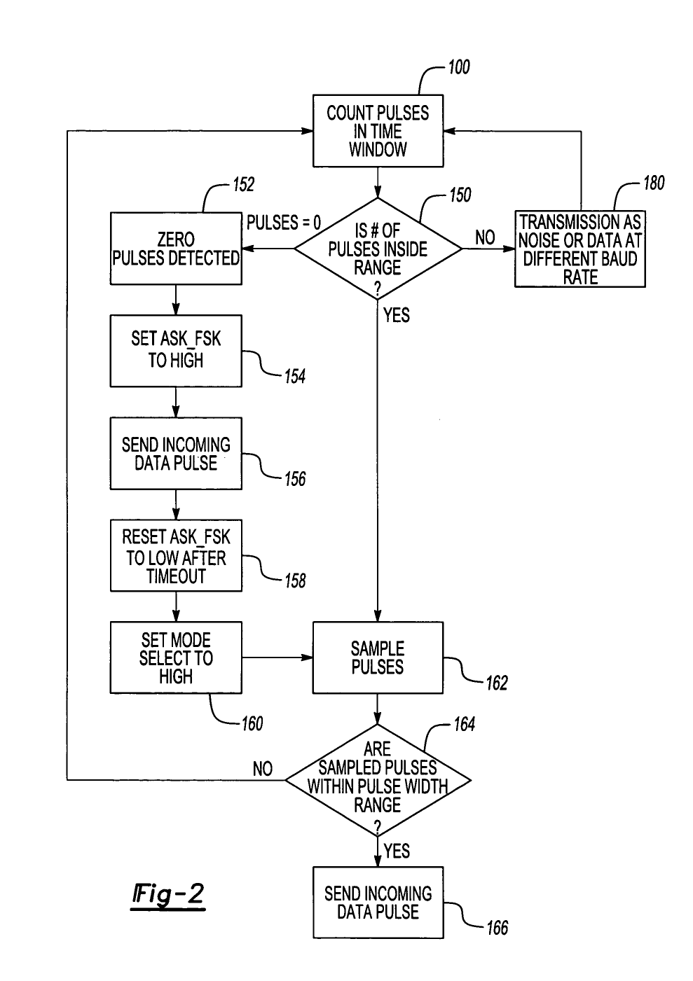

FIG. 2 is a flow diagram illustrating a signal discrimination process according to one embodiment of the invention. In this embodiment, it is assumed that the system 100 idles in an ASK mode and receives and handles ASK modulated signals by default when the ASK_FSK indicator signal is low (FIG. 3). The discriminator 104 first evaluates the incoming data signal received by the receiver 102 by counting the number of pulses in the signal within a selected time window (e.g., 5 ms) (block 150). The size of the time window itself can be selected based on, for example, baud rate, data protocol, noise frequency of the receiver 102, and other factors.

When the receiver 102 is in an ASK mode, a FSK modulated signal will look like one long, continuous pulse in the selected time window, as shown in FIG. 3. As a result, the number of pulses counted in the time window when the FSK modulated signal is being received will be zero. If zero pulses are detected in the selected time window (block 152), the discriminator 104 will set the ASK_FSK signal to a high level (block 154) to indicate to the system processor 103 that the incoming data signal is FSK modulated. The discriminator 104 will also send an incoming data pulse to the system processor 103 to indicate that valid incoming data is being received (block 156). In one embodiment, the ASK_FSK signal resets itself by returning to a low level after a predetermined time-out period (block 158), even if the receiver 102 continues to receive FSK modulated signals.

Once the system processor 103 senses that the ASK_FSK signal indicates an FSK operating mode, the system processor 103 switches the receiver 102 to an FSK mode after a selected delay by setting a mode select signal to a high level in this example (block 160) When the system processor 103 has selected the FSK mode for the receiver 102, the receiver 102 is able to receive FSK modulated signals as data at any time. As long as the mode select signal sent to the receiver 102 is high, the receiver 102 will remain in the FSK mode. When the system processor 103 determines that there is no more FSK data being received (e.g., if no valid data bits are received after a selected timeout period), the system processor 103 switches the receiver 102 back to the ASK mode. At this point, the discrimination process starts over with the pulse counting step (block 110).

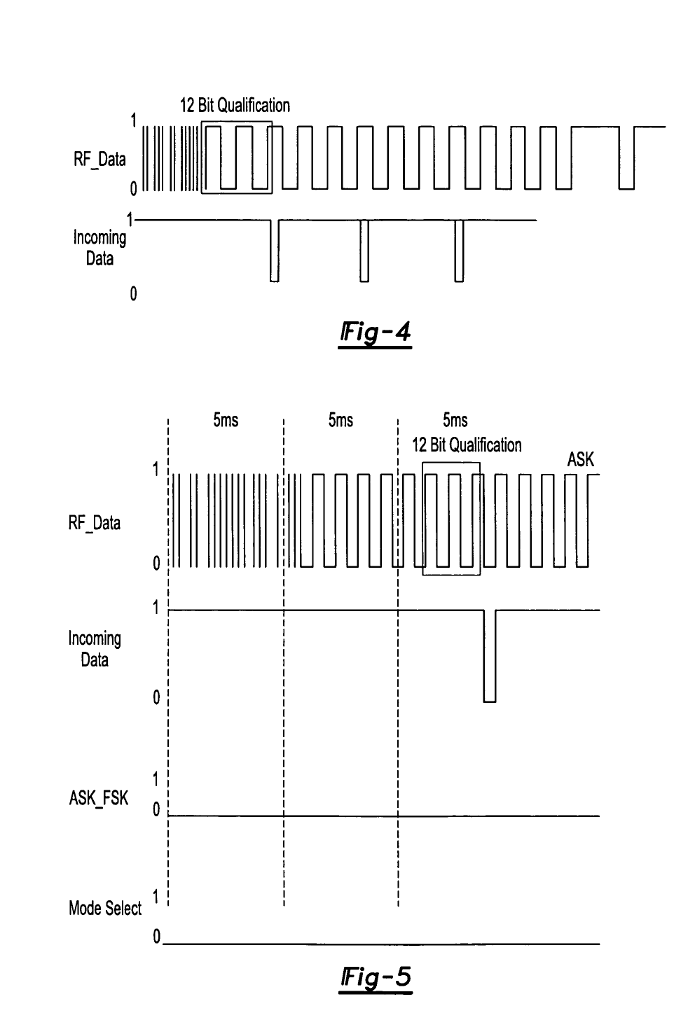

Referring to FIGS. 2 and 4, the discriminator 104 can qualify a portion of the incoming FSK data (e.g., the first two bits of data) via a pulse width discrimination step by sampling the high and low times of the first four half-bits (block 162). If the pulse widths of all four half-bits are within a selected valid time interval for the given baud rate or rates (block 164), the bits are qualified and the discriminator 104 sends the incoming data pulse to the system processor 103 to notify the system processor 103 that a valid signal has been detected (block 166). The discriminator 104 then continues to send the incoming data pulses as long as there is FSK data being sent to the receiver 102. If the half-bit qualification fails, the qualification process is restarted to the pulse counter step (block 110).

If the system processor 103 does not receive FSK data for a selected time period, the system processor 103 switches the mode select signal back to a low level, causing the receiver 102 to switch back to an ASK mode. The system processor 103 can detect this by qualifying incoming pulses with the known baud rate and encoding.

Referring to FIGS. 2 and 5, when the incoming transmission is ASK modulated, the counter discrimination step is conducted to determine whether the number of pulses in the time window is within a selected range (block 150). If it is, it indicates that the transmission may contain incoming ASK modulated data. The discriminator 104 then conducts the pulse width discrimination step in the same way as in the FSK case. More particularly, the discriminator 104 qualifies a selected number of bits by sampling the high and low times of, for example, four half-bits (block 162) and comparing the pulse widths of the four half-bits with a selected valid time interval (block 164). Note that the ASK and FSK qualifications will be different if the ASK and FSK baud rates and different.

If the pulse widths of the sampled bits are within a valid time interval for a given baud rate, then the discriminator 104 sends the incoming data pulse to the system processor 103 and continues to do so periodically as long as the receiver 102 is receiving ASK modulated data (block 166). The mode select signal from the system processor 103 to the receiver 102 in this case will stay at a low level because the receiver 102 is in an ASK mode and does not switch to the FSK mode.

If the number of pulses in the ASK modulated signal are outside of the selected range (block 150), the discriminator 104 treats the incoming transmission as noise or data at a different baud rate (block 180). At this point, the process is restarted at the pulse counter step (block 110).

As shown in FIG. 1, the discriminator 104 may receive a duty cycle control signal from the system processor 103 to control the operation of the receiver 102. The duty cycle control signal enables or disables a duty cycle to the receiver 102. More particularly, the discriminator 104 turns the receiver 102 on continuously if the duty cycle control signal is cleared and turns the receiver 102 on and off according to a duty cycle of a pulse width modulated signal if the duty cycle control signal is set. Duty cycle control may be implemented while the system 100 is idle. By supplying power to the receiver 102 only intermittently when it is idle, the system processor 103 can reduce the total current consumption of the system.

By using a discriminator that discriminates between ASK and FSK modulated signals, the invention makes it possible to use a single receiver to handle both types of signals even when the modulation of a given input signal changes without advance warning. In addition to detecting the difference between FSK and ASK modulated signals, the invention can also determine whether an incoming signal contains valid data, such as Manchester or variable pulse width encoded data, at different baud rates.

It should be understood that various alternatives to the embodiments of the invention described herein may be employed in practicing the invention. It is intended that the following claims define the scope of the invention and that the method and apparatus within the scope of these claims and their equivalents be covered thereby.

1. A signal discrimination method, comprising:
receiving a signal transmission;
counting a number of pulses in the signal transmission within a time window, wherein the signal transmission is a first type if the number of pulses in the window is zero and a second type if the number of pulses in the window is within a predetermined range; and
selecting a first receiving mode if the signal transmission is the first type and selecting a second receiving mode if the signal transmission is the second type.

2. The method of claim 1, wherein the first type is frequency-shift-keyed (FSK) modulated and the second type is amplitude-shift-keyed (ASK) modulated.

3. The method of claim 1, further comprising:
sampling a plurality of bits in the signal transmission;
comparing pulse widths of said plurality of bits with a selected time interval; and
sending an incoming data signal if the pulse widths are within the selected time interval.

4. A signal discrimination method, comprising:
receiving a signal transmission in a receiver and a discriminator;
counting a number of pulses in the signal transmission within a time window in the discriminator;
indicating that the signal transmission is frequency-shift-keyed (FSK) modulated if the number of pulses in the window is zero;
indicating that the signal transmission is amplitude-shift-keyed (ASK) modulated in the signal transmission if the number of pulses in the window is within a predetermined range; and
notifying a system processor of whether the signal transmission is ASK modulated or FSK modulated.

5. The method of claim 4, further comprising selecting a receiving mode in the receiver based on whether the signal transmission is ASK modulated or FSK modulated.

6. The method of claim 5, wherein the selecting step is conducted by a mode select signal sent to the receiver from the system processor.

7. The method of claim 4, wherein the selecting step is conducted by the system processor selecting a state of an indicator signal sent to the receiver.

8. The method of claim 4, further comprising:
sampling a plurality of bits in the signal transmission;
comparing pulse widths of said plurality of bits with a selected time interval; and
sending an incoming data pulse to the system processor if the pulse widths are within the selected time interval, indicating that the signal transmission contains valid data.

9. The method of claim 8, further comprising repeating the sending step as long as the receiver receives valid data.

10. The method of claim 4, further comprising selectively enabling a duty cycle to the receiver, wherein the receiver is powered continuously when the duty cycle is disabled and powered intermittently when the duty cycle is enabled.

11. A receiving system that evaluates a signal transmission, comprising:
a receiver that receives the signal transmission; and
a discriminator that discriminates the signal transmission by
counting a number of pulses in the signal transmission within a time window in the discriminator,
indicating that the signal transmission is frequency-shift-keyed (FSK) modulated if the number of pulses in the window is zero, and
indicating that the signal transmission is amplitude-shift-keyed (ASK) modulated if the number of pulses in the window is within a predetermined range, wherein the discriminator notifies a system processor of whether the signal transmission is ASK modulated or FSK modulated.

12. The receiving system of claim 11, wherein the receiver receives a mode select signal from the system processor based on whether the signal transmission is ASK modulated or FSK modulated.

13. The receiving system of claim 11, wherein the discriminator determines a presence of valid data in the signal transmission by
sampling a plurality of bits in the signal transmission;
comparing pulse widths of said plurality of bits with a selected time interval, and
sending an incoming data pulse to the system processor if the pulse widths are within the selected time interval, indicating that the signal transmission contains valid data.

14. The receiving system of claim 11, wherein the receiver is powered continuously when a duty cycle to the receiver is disabled and powered intermittently when the duty cycle is enabled.
